(19) United States
(12) Patent Application Publication
(10) Pub. No.: US 2011/0074432 A1
(43) Pub. Date: Mar. 31, 2011

(54) METHODS AND APPARATUS FOR BATTERY TESTING

(75) Inventor: Joern A. Tinnemeyer, Richmond (CA)

(73) Assignee: CADEX ELECTRONICS INC., Richmond, BC (CA)

(21) Appl. No.: 12/994,847

(22) PCT Filed: Jun. 5, 2009
(86) PCT No.: PCT/CA09/00777

§ 371 Date: Nov. 26, 2010

Related U.S. Application Data
(60) Provisional application No. 61/059,151, filed on Jun. 5, 2008.

(51) Int. Cl. G01N 27/416; G01R 33/12

(52) U.S. Cl. 324/426; 324/239

(57) ABSTRACT

Methods and apparatus for testing electrical storage batteries monitor magnetic susceptibility of components of the storage batteries. In some embodiments, magnetic susceptibility of a plate in a lead-acid battery is determined to provide an indication of the state of charge of the battery.

### CROSS-REFERENCE TO RELATED APPLICATIONS

This application claims priority from U.S. patent application No. 61/059,151 filed on 5 Jun. 2008 and entitled: METHODS AND APPARATUS FOR BATTERY TESTING. For purposes of the United States, this application claims the benefit of application No. 61/059,151 under 35 U.S.C. §119.

### TECHNICAL FIELD

The invention relates to battery testing. Certain embodiments of the invention relate to testing lead-acid batteries.

### BACKGROUND

Batteries are used to supply electricity in a wide range of applications. In the automotive field, batteries are used to supply power for vehicle systems which may include engine starting, lighting, electronic accessories, propulsion, control systems and the like. Newer vehicles include an increasing number of systems that require electricity for operation. Some, such as electronically controlled braking systems and electronic engine control systems, are vital to safe vehicle operation.

Where a critical system is powered by a battery then it can be important to monitor the state of the battery. Battery testing systems are used to evaluate the state of charge (SoC) of batteries as well as the condition (sometimes referred to as the state of health (SoH)) of batteries. Battery testing systems typically monitor electrical characteristics of batteries. For example, some such systems monitor the impedance of a battery at various frequencies.

A problem with many existing battery testing systems is that the systems are not accurate, especially for batteries that are not new. Such systems can yield estimates of a battery's state of charge that are inaccurate.

There is a need for accurate systems and methods for monitoring the state of batteries.

### BRIEF DESCRIPTION OF THE DRAWINGS

The appended drawings illustrate non-limiting embodiments of the invention.

FIG. 1 is a block diagram of a battery testing system according to an example embodiment of the invention.

FIG. 2 shows an apparatus according to a more detailed example embodiment.

FIG. 3 illustrates the magnetic field produced by an electrical current circulating in a circular loop.

FIG. 4 is a schematic illustration of a magnetic field sensor.

FIG. 5 is a graph which includes a curve illustrating measured magnetic susceptibility of a battery electrode as a function of the state of charge of the battery.

FIG. 6 shows a sensor assembly.

FIG. 7 is a flowchart showing an example method for monitoring the state of a battery.

### DESCRIPTION

Throughout the following description, specific details are set forth in order to provide a more thorough understanding of the invention. However, the invention may be practiced without these particulars. In other instances, well known elements have not been shown or described in detail to avoid unnecessarily obscuring the invention. Accordingly, the specification and drawings are to be regarded in an illustrative, rather than a restrictive, sense.

Apparatus and methods according to this invention measure battery state based on changes in the magnetic susceptibility of battery components. The battery component may comprise an electrode of the battery that undergoes a chemical change as the battery is charged or discharged.

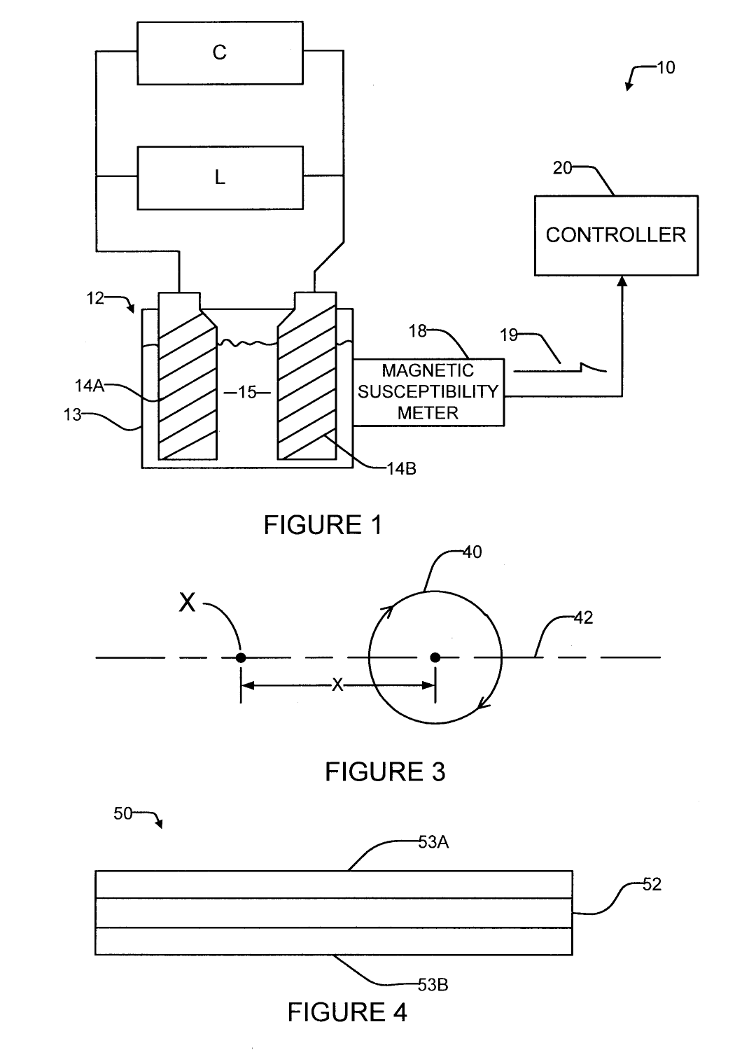

FIG. 1 shows a battery testing apparatus 10 connected to test a battery 12. Battery 12 comprises a case 13 housing electrodes 14A and 14B (collectively electrodes 14) immersed in an electrolyte 15. In FIG. 1, battery 12 is illustrated as having only one cell. Battery 12 may have any suitable number of cells. Battery 12 can deliver electrical power to a load L and can be charged by a charger C.

The chemical composition of at least one of electrodes 14 changes as the battery is charged and discharged. Consider, for example, the case where battery 12 is a lead-acid battery. In a lead acid battery electrode 14B comprises a lead anode and electrode 14A comprises a lead dioxide cathode. Electrolyte 15 is an acid electrolyte.

During discharge, the following half reaction occurs at anode 14B:

Pb+HSO₄⁻→PbSO₄+H⁺+2e⁻ (1)

And the following half reaction occurs at cathode 14A:

Pb²⁺+SO₄²⁻→PbSO₄ (2)

During charging, the reactions at each electrode are reversed. What is of interest is that the chemical composition of each electrode changes as the battery is charged and discharged.

Apparatus 10 exploits changes in the magnetic susceptibility of an electrode 14, which correspond to the chemical changes in the electrode 14, to derive information indicative of the state of battery 12. For example, apparatus 10 may derive information indicative of the state of charge of battery 12. Magnetic susceptibility is a measure of the degree to which a material becomes magnetized in response to an applied magnetic field.

Lead has a magnetic susceptibility of −23×10⁻⁶ in cgs units while lead sulfate has a magnetic susceptibility of about −70×10⁻⁶. Thus, as battery 12 is discharged and the ratio of lead sulfate to lead in anode 14B increases, the magnetic susceptibility of anode 14B also increases (i.e., anode 14B become more diamagnetic, and will exhibit greater magnetization in response to a given applied magnetic field). Similarly, as battery 12 is charged, the ratio of lead sulfate to lead in anode 14B decreases and the magnetic susceptibility of anode 14B decreases (i.e., anode 14B become less diamagnetic, and will exhibit less magnetization in response to a given applied magnetic field). Thus, the magnetic susceptibility of anode 14B can be correlated to the state of charge of battery 12. The magnetic susceptibility of cathode 14A also changes with the state of charge of battery 12 but the changes at cathode 14A are smaller than the changes in magnetic susceptibility of anode 14B because the difference between the magnetic susceptibilities of lead dioxide and lead sulfate is smaller than the difference between the magnetic susceptibilities of lead and lead sulfate.

In the embodiment of FIG. 1, apparatus 10 comprises a magnetic susceptibility meter 18 which provides an output signal 19 that changes in response to changes in the magnetic susceptibility of anode 14B. Signal 19 is provided to a controller 20. Controller 20 takes action based on the value of signal 19. Examples of actions that may be taken by controller 20 in various applications include:
Computing and displaying an estimate of state of charge. The estimate may be in arbitrary units such as 0 to 10, 0 to 100, GOOD-FAIR-POOR or the like. The estimate may be displayed in terms of numerical or other charge values and/or in the form of a bar graph or other visual display.
Shutting down and/or placing into a reduced power mode one or more components that are included in load L in response to determining that the state of charge is below a threshold.
Generating a warning signal to alert an operator that the state of charge is below a threshold. The warning may be a visual or audible warning or an electronic signal delivered to another control system, an electronic message such as an e-mail, instant message or the like, etc.

Controller 20 may comprise a programmed data processor, logic circuits or the like. In some embodiments, controller 20 comprises a calibration function that associates values of signal 19 with values indicative of battery state of charge. The calibration function may comprise a look-up table, a set of one or more parameters of an equation relating values of signal 19 to the state of charge of battery 12 or the like.

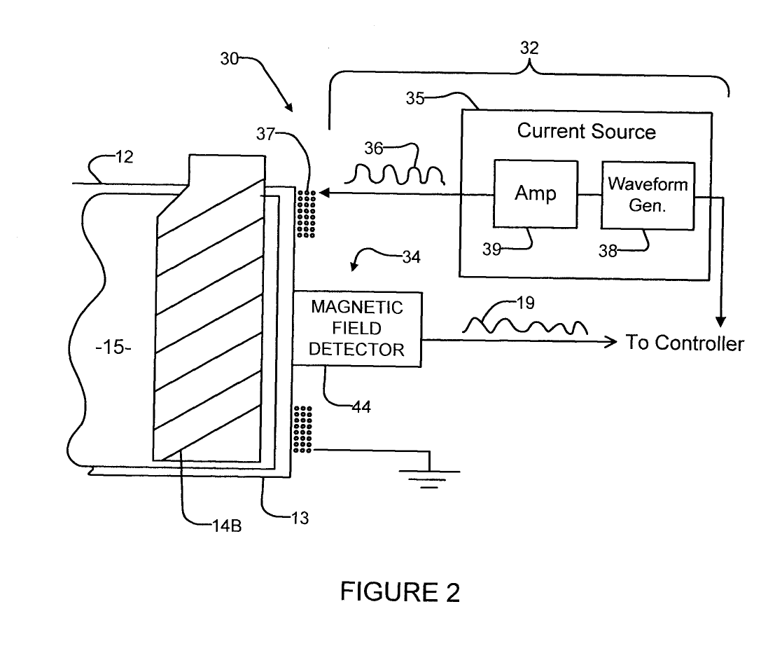

FIG. 2 shows apparatus 30 according to a more detailed example embodiment. Apparatus 30 comprises a magnetic field source 32 and a magnetic field detector 34. In the illustrated embodiment, magnetic field source 32 and magnetic field detector 34 are mounted on the outside of case 13 adjacent to an electrode 14B. In the illustrated embodiment, magnetic field source 32 comprises an electrical current source 35 that is connected to pass electrical current through a conductor 37. Preferably conductor 37 has multiple windings so that a magnetic field large enough to obtain a measure of the magnetic susceptibility of electrode 14B can be achieved at relatively low levels of electric current supplied by current source 35. For example, conductor 37 may be in the form of a coil or spiral. In some embodiments, conductor 37 is provided as part of an assembly that can be adhered to case 13. The assembly may have a self-adhesive face or self-adhesive patches to allow the assembly to be affixed to case 13.

In some embodiments, conductor 37 is patterned on a circuit board. Conductor 37 may, for example, comprise a spiral patterned on a circuit board. The circuit board may have multiple layers each patterned with a conductor such that magnetic fields generated by current passing through the conductors of each layer reinforce one another. In other embodiments, conductor 37 may comprise one or more coils of fine wire.

Current source 35 may provide a current 36 that is time-varying such that the magnetic field of conductor 37 is time varying. This may cause signal 19 to be time-varying. Controller 20 may use the time variations in signal 19 to reject noise. The noise will not vary with time in the same way as current 36. In the example embodiment illustrated in FIG. 2, current source 35 comprises a waveform generator 38 coupled to drive an amplifier 39. The output of amplifier 39 is connected to drive a current in conductor 37. In some embodiments, the magnetic field is time varying at a frequency in the range of 1 kHz to 20 kHz.

FIG. 3 illustrates the magnetic field produced by an electrical current circulating in a circular loop 40. From the Biot-Savart Law it can be shown that the magnetic field produced at a point X on the axis 42 of loop 40 is given by:

$${B}_{0} ( x ) = \frac{{μ}_{0} {nIR}^{2}}{2 {( {R}^{2} + {x}^{2} )}^{3 / 2}} \qquad ( 3 )$$

where:
x is the distance of point X along axis 42 from the plane of loop 40;
B₀(x) is the magnetic field at point X;
μ₀(x) is the magnetic constant (the permeability of free space where loop 40 and the surrounding areas are devoid of matter);
n is the number of turns in loop 40;
I is the current flowing in loop 40; and
R is the radius of loop 40.

If there is a material at point X then the magnetic field from current loop 40 will induce magnetism in the material. The magnitude, M, of the magnetization of the material depends upon the magnetic susceptibility of the material and the strength of the field B₀. The magnetic field at a point away from point X will be perturbed by the magnetization of the material at point X. Therefore, changes in the magnetic susceptibility of material in the vicinity of point X can be monitored by measuring changes in the magnetic field at a location away from point X. The magnetic field could be measured, for example, in the plane of current loop 40. In some embodiments, magnetic field detector 34 is located substantially in the plane of current loop 40 inside current loop 40, for example at the center of current loop 40.

In the embodiment illustrated in FIG. 2, magnetic field detector 34 comprises a sensor 44 located on-axis with and substantially in the plane of conductor 37. Sensor 44 and conductor 37 may be mounted in an assembly that is attachable to case 13 of battery 12 adjacent to an electrode 14B.

Sensor 44 has a sensitivity sufficient to detect changes in the magnetic field resulting from changes in the susceptibility of the material of an adjacent electrode 14B. Sensor 44 may optionally comprise a flux concentrator to amplify the magnetic field to be detected. In some embodiments, sensor 44 comprises a magnetic tunnel junction (MTJ). Such sensors are available, for example, from Micro Magnetics Inc. of Fall River Mass., USA. Magnetic field sensors based on a MTJ are described in:
Shen et al. In situ detection of single micron-sized magnetic beads using magnetic tunnel junction sensors, Appl. Phys. Lett. 86, 253901 (2005);
B. D. Schrag et al. Magnetic current imaging with magnetic tunnel junction sensors: case study and analysis.

A simple MTJ comprises two layers of magnetic material separated by a very thin insulating film. If a voltage is applied across this structure and the insulating layer is thin enough, electrons can flow by quantum mechanical tunnelling through the insulating film. For tunnelling between two magnetized materials, the tunnelling current is maximum if the magnetization directions of the two materials are parallel and minimum if they are aligned antiparallel. Therefore, the tunnelling current, and thus the resistance of the device, will change as external magnetic fields alter the relative magnetic orientations of the layers of magnetic material.

Other magnetic sensors that are sensitive enough to detect changes in the magnetic field resulting from changes in the magnetic susceptibility of battery components may also be used. For example, magneto-electric sensors may be applied. Magnetic field sensors based in the giant magnetoelectric effect are described, for example, in:
Nan et al. Large magnetoelectric response in multiferroic polymer-based composites Phys. Rev. B 71, 014102 (2005).
Ryu et al., Magnetoelectric Effect in Composites of Magnetostrictive and Piezoelectric Materials Journal of Electroceramics, vol. 8, No. 2, pp. 107-119 (August 2002).
Z P Xing et al., Modeling and detection of quasi-static nanotesla magnetic field variations using magnetoelectric laminate sensors Meas. Sci. Technol. 19 015206 (2008)
Podney, U.S. Pat. No. 5,675,252.

FIG. 4 shows a magnetic field sensor 50 comprising a layer 52 of the giant magnetorestrictive material Terfenol-D sandwiched between layers 53A and 53B of piezoelectric material. The piezoelectric materials may comprise, for example, lead zirconate titanate (“PZT”). Changes in the magnetic field cause magnetostriction in layer 52. This, in turn, causes piezolayers 53A and 53B to change shape and to create a voltage differential between electrodes on the piezolayers. In some embodiments, sensor 50 is designed to have an electromechanical resonant frequency such that sensor 50 is most sensitive at a frequency at or near a frequency of the driving current provided by current source 35.

Other sensitive magnetic field sensors that may have application in some embodiments include:
Superconducting Quantum Interference Detectors (SQUIDS). SQUIDs are very sensitive but may require special operating conditions that may make them unsuitable for some applications.
Sensors exploiting giant magnetoresistance (GMR).
Fiber optic magnetometers.
Sensors exploiting tunnelling magnetoresistance (TMR).
Search coil magnetometers.
Magnetotransistors as described, for example in A. Nathan et al., How to achieve nanotesla resolution with integrated siliconmagnetotransistors, Electron Devices Meeting, 1989. IEDM '89, pp. 511-514 (3-6 Dec. 1989).
Ultra-senstitive Hall effect sensors as described, for example, in

Nguyen Van Dau F., Magnetic sensors for nanotesla detection using planar Hall effect, Sensors and actuators. A, 1996, vol. 53, no 1-3, pp. 256-260.

The sensitivity required for magnetic field sensor 50 will depend on factors including: the strength of the magnetic field generated by magnetic field source 32; the geometries of magnetic field source 32 and magnetic field sensor 50; the geometry of the electrode 14 in which chemical changes occur; and the distances between magnetic field source 32, magnetic field sensor 50, and the electrode 14.

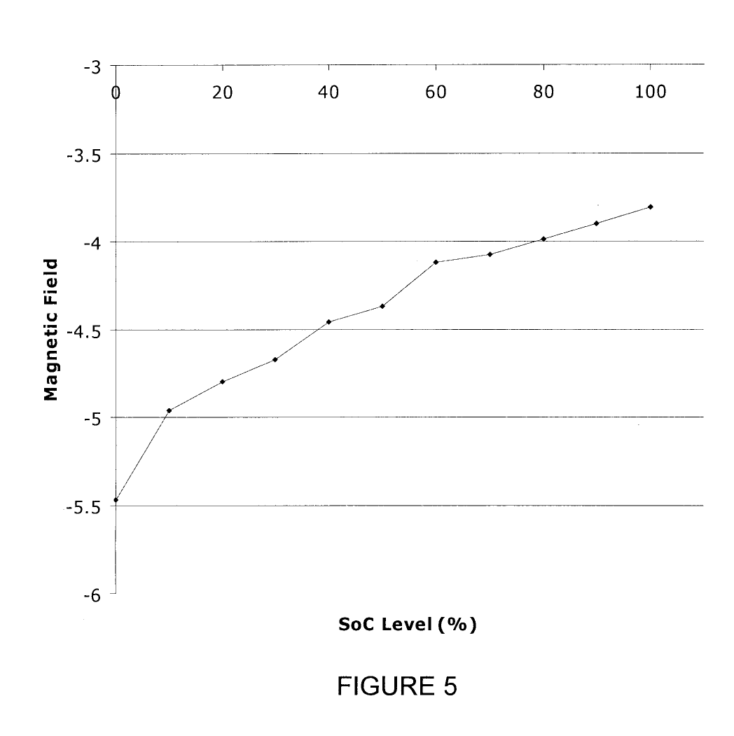

FIG. 5 is a graph which includes a curve illustrating measured magnetic susceptibility of a battery electrode as a function of the state of charge of the battery. It can be seen that there is a strong correlation between the detected magnetic field and the state of charge of the battery being tested. The graph of FIG. 5 was obtained using an AGM SLI (starting lighting ignition) battery with a capacity of 90 Ahr. Measurements were made using a 25 A discharge current from a fully charged battery down to a voltage of 10.5 V at 20° C. The sensor was located directly on the side of the battery adjacent to one electrode.

In some embodiments, the frequency of electrical current source 35 is variable. Such embodiments may obtain additional information regarding a battery by monitoring magnetic susceptibility of a battery component at two or more different frequencies. The depth of penetration of a magnetic field into a material decreases as frequency increases. The penetration depth is approximated by the skin depth given by:

$$ϛ = \frac{1}{\sqrt{πμθ f}} \qquad ( 4 )$$

where: ζ is the skin depth; μ, is the magnetic susceptibility of the material; θ is the electrical conductivity of the material and f is the frequency. At 10 kHz, ζ is about 2 mm in some materials of interest. By making measurements using magnetic fields which fluctuate at different frequencies (e.g. by varying the frequency of AC or pulsed DC current driving an electromagnet that generates a magnetic field), one can sense the degree to which chemical changes associated with charging or discharging a battery have occurred at different depths within an electrode of a battery.

In some embodiments, a tester according to the invention measures magnetization of an electrode of a battery under test in response to magnetic excitation at two or more frequencies and bases a determination of the state of charge of the battery on the measured magnetization at each of the two or more frequencies. Measurements at different frequencies may be made at different times or at the same time. Obtaining the measure of state of charge may comprise, for example taking an average or weighted average of values obtained for the two or more frequencies of magnetic excitation.

Some embodiments comprise a control system configured to adjust a frequency of magnetic excitation to a frequency that suits a particular battery. This may be done, for example, by varying the frequency to at least approximately identify a transition frequency that is the highest frequency at which the magnetic field fully penetrates the electrode being monitored. The transition frequency may be identified, for example, by sweeping the frequency down from a high frequency and determining the frequency at which the detected magnetism exhibits characteristics that indicate that the magnetic field of electrolyte on a far side of the electrode is being detected.

Some embodiments provide a sensor assembly that comprises a substrate that is attachable to a case of a battery and, supported on the substrate, some or all of:
A coil or other magnetic field source.
A magnetic field detector.
Signal processing circuitry connected to provide preliminary processing for a signal output by the magnetic field detector. The signal processing circuitry may comprise, for example, one or more of: an amplifier, one or more filters (which may serve as a bandpass filter), and artefact rejection circuits.
A driving circuit for the magnetic field detector. The driving circuit may comprise, for example, a circuit that provides suitable bias voltages and/or supplies electrical current to the magnetic field detector.
   In some embodiments, the sensor assembly comprises adhesive spots or an adhesive layer that permits a face of the sensor assembly to be adhered to a face of a battery. In some embodiments all circuitry and other components on the substrate are encapsulated or otherwise protected. In some embodiments the outer case of a battery has a recess and the sensor assembly is affixed to the battery in the recess. In such embodiments the sensor assembly is protected somewhat against mechanical damage by being inlaid into a face of the battery. In some embodiments the substrate is flexible so that it can conform well to a surface of the battery. In some embodiments the substrate is generally planar so that it can conform to a generally planar face of a battery. In some embodiments the substrate is curved so that it can conform to a curved face of a battery.

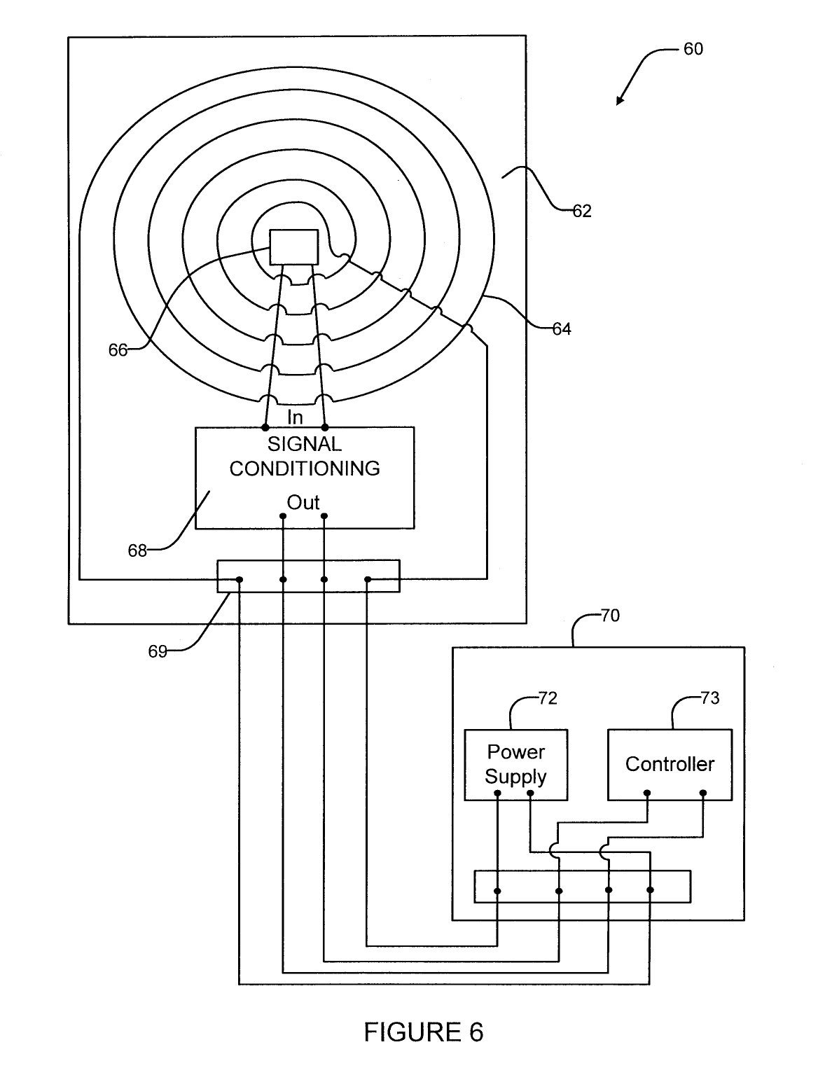

FIG. 6 shows a sensor assembly 60 comprising a substrate 62, coils 64 for generating a magnetic field, a magnetic field detector 66 and signal processing circuits 68. A connector 69 permits connection to an external apparatus 70 which includes a power supply 72 for supplying current to coils 64 and a controller 73 which evaluates a state of a battery based at least in part on signals from magnetic field detector 66 and takes actions such as:
Displaying a state of charge of the battery on a display.
Computing an estimated run-time before the battery reaches a predetermined state of charge.
Disconnecting optional loads and/or shifting loads into power-conserving modes in response to a determination that the state of charge of the battery has fallen to below a threshold level.
Signalling to other components to indicate a state of charge of the battery.
etc.
   In some embodiments, the battery is a battery in a vehicle and external apparatus 70 is connected to a data communication bus of the vehicle. In some embodiments the data communication bus is a Controller Area Network (“CAN”) or Local Interconnect Network (“LIN”) bus. Apparatus 70 may send signals over the data communication bus to other components. The signals may cause the other components to switch to a different operating mode and/or shut down or start up as a result of a change in the state of a battery being monitored.

Alternative embodiments differ from the example apparatus described above in various ways. For example:
A permanent magnet could be used in place of an electromagnet to generate a magnetic field.
A battery testing apparatus may operate as described herein and also receive other information regarding a battery. For example, characteristics such as: the complex impedance of the battery at different frequencies, the charge or discharge current of the battery, and/or the voltage of the battery may be monitored. These additional measurements may be combined with information from magnetic susceptibility measurements as described herein to obtain enhanced information regarding the state of the battery being monitored.
Some components of a battery testing apparatus could be built into a battery. For example, a magnetic field sensor could be embedded within a battery electrode. A coil for inducing a magnetic field in a battery electrode could be located inside a battery case and could be embedded within a battery electrode. A magnetic field sensor and coil could be embedded within a wall of a battery case.
An applied magnetic field could be generated by current flowing in the battery for supply to a load. Apparatus may include a current sensor that monitors current supplied by the battery and correlates fluctuations in the supplied current to fluctuations in a detected magnetic field.

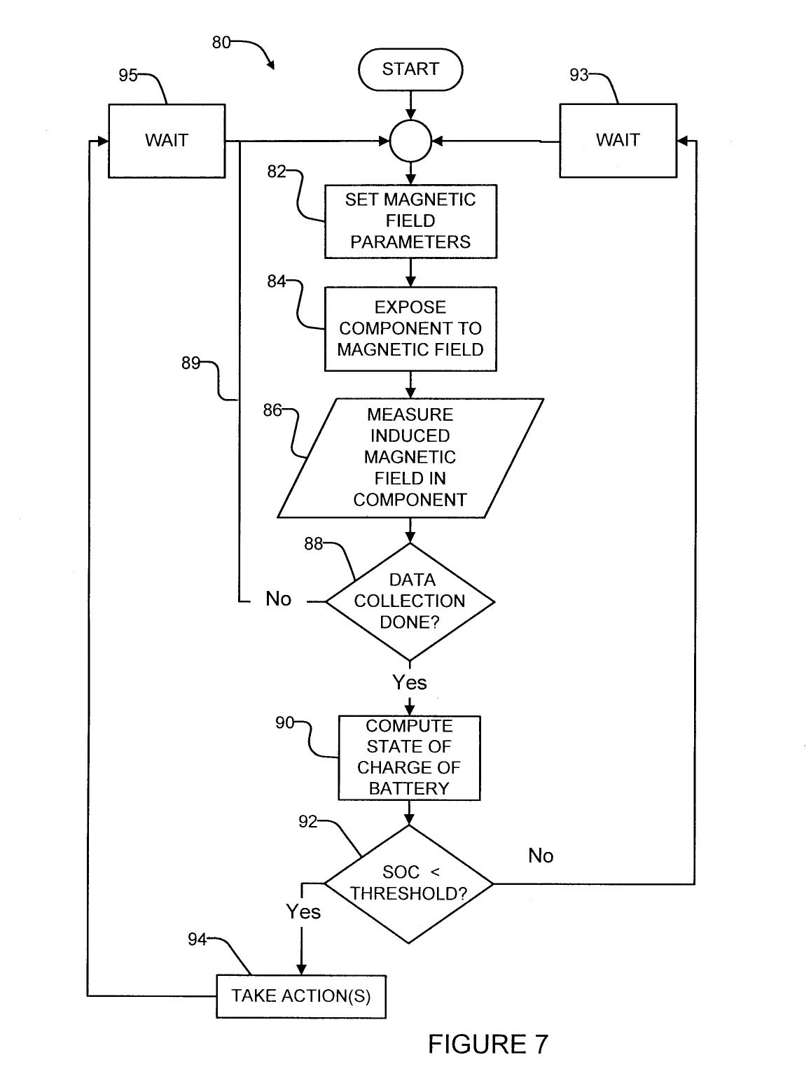

FIG. 7 is a flowchart illustrating a method 80 according to some example embodiments of the invention. Magnetic field parameters are optionally set in block 82. In block 84 a battery component is exposed to at least a first magnetic field. A magnetic field induced in the battery component is measured in block 86.

In some embodiments, multiple magnetic fields induced in the component are measured. In such embodiments, different magnetic fields (e.g. magnetic fields having different intensities, different polarizations or different time variations may be used for some or all of the multiple measurements. In such embodiments, block 88 determines whether data collection is complete. If not, method 80 repeats blocks 82, 84 and 86 to obtain an additional measurement as indicated by path 89.

When data collection is complete (YES result from block 88) method 80 proceeds to block 90 which determines the state of the battery from the collected data. The state determined in block 90 may comprise the State of Charge of the battery. In block 92 the state of charge is compared to a threshold. If the comparison indicates that the battery is charged sufficiently then method 80 proceeds to block 93 and waits until an appropriate time to measure the state of the battery again. If block 92 determines that the state of charge of the battery is lower than some threshold then one or more appropriate actions are taken in block 94 due to a threshold being exceeded and then method 80 proceeds to block 95 and waits until an appropriate time to measure the state of the battery again.

The invention may be embodied in a range of ways including, without limitation:
Methods for monitoring the state (particularly the state of charge) of batteries.
Apparatus for testing the state (particularly the state of charge) of batteries.
Batteries having built in components for use in monitoring according to a method as described herein.
Sensor assemblies that can be attached to batteries for use in monitoring according to a method as described herein.

Certain implementations of the invention comprise computer processors which execute software instructions which cause the processors to perform a method of the invention. For example, one or more processors in a battery tester may implement methods for determining the state of charge of batteries based on measured induced magnetic fields by executing software instructions in a program memory accessible to the processors. The invention may also be provided in the form of a program product. The program product may comprise any medium which carries a set of computer-readable instructions which, when executed by a data processor, cause the data processor to execute a method of the invention. Program products according to the invention may be in any of a wide variety of forms. The program product may comprise, for example, magnetic data storage media including floppy diskettes, hard disk drives, optical data storage media including CD ROMs, DVDs, electronic data storage media including ROMs, flash RAM, or the like. The computer-readable signals on the program product may optionally be compressed or encrypted.

Where a component (e.g. a software module, processor, assembly, device, circuit, sensor, etc.) is referred to above, unless otherwise indicated, reference to that component (including a reference to a“means”) should be interpreted as including as equivalents of that component any component which performs the function of the described component (i.e., that is functionally equivalent), including components which are not structurally equivalent to the disclosed structure which performs the function in the illustrated exemplary embodiments of the invention.

While a number of exemplary aspects and embodiments have been discussed above, those of skill in the art will recognize certain modifications, permutations, additions and sub-combinations thereof. It is therefore intended that the following appended claims and claims hereafter introduced are interpreted to include all such modifications, permutations, additions and sub-combinations as are within their true spirit and scope.

1. A method for determining a state of an electrochemical battery, the method comprising determining a magnetic susceptibility of a component of the battery.

2. A method according to claim 1 wherein determining the magnetic susceptibility of the component comprises exposing the component to a magnetic field and measuring an induced magnetic field created in the component by the magnetic field.

3. A method according to claim 2 comprising causing the magnetic field to vary at a frequency.

4. A method according to claim 3 wherein the frequency is in the range of 1 kHz to 20 kHz.

5. A method according to claim 2 comprising determining a state of the battery from an association of that state with the magnetic susceptibility.

6. A method according to claim 3 comprising varying the frequency at which the magnetic field varies and identifying a transition frequency.

7. A method according to claim 6 comprising, after identifying the transition frequency, causing the magnetic field to vary at the transition frequency.

8. A method for determining a state of an electrochemical battery, the method comprising:
exposing a component of the battery to a first magnetic field, the first magnetic field time-varying at a first frequency;
measuring a first induced magnetic field created in the component by the first magnetic field; and
determining a state of the battery based at least in part on a magnitude of the first induced magnetic field.

9. A method according to claim 8 comprising:
exposing the component to a second magnetic field, the second magnetic field time-varying at a second frequency different from the first frequency;
measuring a second induced magnetic field created in the component by the second magnetic field; and
determining the state of the battery based in part on a magnitude of the second induced magnetic field.

10. A method according to claim 9, wherein determining the state of the battery comprises determining a magnetic susceptibility of the component from the magnitude of the second induced magnetic field.

11. A method according to claim 9 wherein determining the state of the battery comprises determining a weighted average of magnitudes of at least said first and second induced magnetic fields.

12. A method according to claim 10 wherein determining the state of the battery comprises determining a skin depth of the first magnetic field.

13. A method according to claim 1 wherein the component is an electrode of the battery.

14. A method according to claim 13 wherein the battery is a lead-acid battery.

15. A method according to claim 13 wherein the electrode is adjacent to a wall of a case of the battery and the method comprises measuring at a location outside of the case a magnetic field resulting from magnetism induced in the electrode.

16. A method according to claim 1 wherein the component is an anode of the battery.

17. A method according to claim 1 wherein the state is a state of charge of the battery.

18. Apparatus for determining a state of an electrochemical battery, the apparatus comprising:
a magnetic field detector positionable to determine a magnetization of a component of the electrochemical battery as a result of an applied magnetic field.

19. Apparatus according to claim 18 comprising:
a) a magnetic susceptibility meter configured to output a signal indicative of a magnetic susceptibility of a battery component; and
b) a controller connected to receive the signal and configured to determine an estimate of a state of charge of the battery, the estimate based at least in part on the signal.

20. Apparatus according to claim 19 wherein the controller is configured to display on a display the estimate of a state of charge of the battery.

21. Apparatus according to claim 19 wherein the controller is configured to reduce the electrical power drawn by one or more loads to which the battery supplies electrical power in response to the estimate indicating that the state of charge is below a threshold.

22. Apparatus according to claim 19 comprising a visible or audible warning device wherein the controller is configured to activate the warning device in response to the estimate indicating that the state of charge is below a threshold.

23. Apparatus according to claim 19 wherein the controller comprises a calibration function, the calibration function providing a relationship between values of the signal and corresponding states of charge of the battery.

24. Apparatus according to claim 23 wherein the calibration function comprises a lookup table and the controller is operable to look up the state of charge using a value of the signal as a key.

25. Apparatus according to claim 19 wherein the magnetic susceptibility meter comprises a magnetic field source and the magnetic field detector.

26. Apparatus according to claim 25 wherein the magnetic field detector comprises a magnetic tunnel junction.

27. Apparatus according to claim 25 wherein the magnetic field detector is based on the giant magnetoelectric effect.

28. Apparatus according to claim 25 wherein the magnetic field source comprises an electrical current source connected to supply electrical current to an electrical conductor, the electrical conductor comprising at least one winding.

29. Apparatus according to claim 28 wherein the electrical current source is operable to deliver a time varying current in the electrical conductor.

30. Apparatus according to claim 28 wherein the electrical current source is configured to supply electrical current to the electrical conductor at at least first and second different frequencies.

31. Apparatus according to claim 28 wherein the electrical current source is operable to vary a frequency of electrical current supplied to the electrical conductor.

32. Apparatus according to claim 31 wherein the frequency is variable in a range including 10 kHz.

33. Apparatus according to claim 28 wherein the conductor lies in a plane and defines a current loop and the magnetic field detector lies in the plane of the current loop.

34. Apparatus according to claim 28 wherein the electrical conductor comprises a current loop that is symmetrical about an axis and the magnetic field detector lies on the axis.

35. Apparatus according to claim 28 wherein the electrical conductor comprises a spiral conductor patterned on a circuit board.

36. Apparatus according to claim 35 wherein the circuit board is a multi-layer circuit board and the spiral conductor comprises spiral conductor portions patterned on two or more layers of the circuit board.

37. Apparatus according to claim 28 wherein the electrical conductor is mounted on an outside of a case of the battery.

38. Apparatus according to claim 37 wherein the electrical conductor is mounted in a recess on the outside of the case of the battery.

39. Apparatus according to claim 28 wherein the electrical conductor is integrated into a case of the battery.

40. Apparatus according to claim 28 wherein the electrical conductor is provided in an assembly having an adhesive face for attachment to a case of the battery.

41. A sensor assembly for use with a battery, the sensor assembly comprising a magnetic field source and a magnetic field detector.

42. A sensor assembly according to claim 41 comprising signal processing circuitry configured to provide processing of an output of the magnetic field detector.

43. A sensor assembly according to claim 42 wherein the signal processing circuitry comprises an amplifier.

44. A sensor assembly according to claim 41 comprising a driving circuit for the magnetic field detector.

45. A sensor assembly according to claim 41 comprising an adhesive on a face of the sensor assembly, the adhesive suitable for affixing the sensor assembly to a case of a battery.

46. An electrical battery comprising one or more electrodes, the battery characterized by a magnetic field detector located inside a case of the battery.

47. A battery according to claim 46 wherein the magnetic field detector is embedded in at least one of the one or more electrodes.

48. A battery according to claim 46, comprising a source of magnetic field embedded in at least one of the one or more electrodes.

49. A battery according to claim 48 wherein the source of magnetic field comprises a current loop.

50. A battery according to claim 46 wherein the battery is a lead-acid battery.

51. A battery according to claim 46 wherein the magnetic field detector comprises a magnetic tunnel junction.

52. A battery according to claim 46 wherein the magnetic field detector comprises a giant magnetoelectric effect sensor.

53. (canceled)

54. (canceled)
